(19) United States
(12) Patent Application Publication
(10) Pub. No.: US 2026/0371760 A1
(43) Pub. Date: Nov. 19, 2026

(54) OPTICAL ELEMENT, PHOTODETECTOR, AND ELECTRONIC APPARATUS

(71) Applicant: SONY SEMICONDUCTOR SOLUTIONS CORPORATION, Kanagawa (JP)

(72) Inventor: Yu SAWASHIMA, Kanagawa (JP)

(73) Assignee: SONY SEMICONDUCTOR SOLUTIONS CORPORATION, Kanagawa (JP)

(21) Appl. No.: 19/135,762

(22) PCT Filed: Nov. 15, 2023
(86) PCT No.: PCT/JP2023/041034

§ 371 Date: Jun. 4, 2025

(30) Foreign Application Priority Data
Dec. 27, 2022 (JP) 2022-210860

(51) Int. Cl. H10F 39/00

(52) U.S. Cl. CPC H10F 39/806

(57) ABSTRACT

There is provided an optical element. The optical element includes: a structure including a first member and a second member provided around the first member, the second member having a refractive index different from a refractive index of the first member; and a filling material provided around the structure and having a refractive index different from the refractive index of the second member.

### CROSS REFERENCE TO RELATED APPLICATIONS

This application claims the benefit of Japanese Priority Patent Application JP2022-210860 filed Dec. 27, 2022, the entire contents of which are incorporated herein by reference.

### TECHNICAL FIELD

The present disclosure relates to an optical element, a photodetector, and an electronic apparatus.

### BACKGROUND ART

A color separating lens array has been proposed which has a plurality of nanoposts and separately condenses incident light according to wavelengths (PTL 1).

### CITATION LIST

### Patent Literature

[PTL 1] Japanese Unexamined Patent Application Publication No. 2021-69119

### SUMMARY

### Technical Problem

It is desired for an optical element to be able to efficiently condense incident light.

It is desirable to provide an optical element that makes it possible to efficiently condense light.

### Solution to Problem

An optical element according to an embodiment of the present disclosure includes: a structure having a columnar shape and including a first member and a second member provided around the first member and having a refractive index different from a refractive index of the first member; and a material provided around the structure and having a refractive index different from the refractive index of the second member. In embodiments, the structure may have a shape other than a columnar shape, including but not limited to, a rectangular shape (e.g., FIGS. 14 and 17) or a cross shape (e.g., FIG. 15).

A photodetector according to an embodiment of the present disclosure includes: a first light-guiding member including a first structure having a columnar shape and a material provided around the first structure; and a first photoelectric conversion element that photoelectrically converts light incident via the first light-guiding member. The first structure includes a first member and a second member provided around the first member and having a refractive index different from a refractive index of the first member. The material is provided around the first structure and has a refractive index different from the refractive index of the second member. In embodiments, the first structure may be provided above the first photoelectric conversion element and disperses incident light.

An electronic apparatus according to an embodiment of the present disclosure includes: an optical system; and a photodetector that receives light transmitted through the optical system. The photodetector includes a first light-guiding member including a first structure having a columnar shape and a filling material provided around the first structure, and a first photoelectric conversion element that photoelectrically converts light incident via the first light-guiding member. The first structure includes a first member and a second member provided around the first member and having a refractive index different from a refractive index of the first member. The filling material is provided around the first structure and has a refractive index different from the refractive index of the second member.

### BRIEF DESCRIPTION OF DRAWINGS

FIG. 1 is a block diagram illustrating an example of a schematic configuration of an imaging device which is an example of a photodetector according to an embodiment of the present disclosure.

FIG. 2 is a diagram illustrating a configuration example of a pixel of the imaging device according to the embodiment of the present disclosure.

FIG. 3 is a diagram illustrating an example of a planar configuration of the imaging device according to the embodiment of the present disclosure.

FIG. 4 is a diagram illustrating an example of a cross-sectional configuration of the imaging device according to the embodiment of the present disclosure.

FIG. 5A is a diagram illustrating an example of the planar configuration of the imaging device according to the embodiment of the present disclosure.

FIG. 5B is a diagram illustrating an example of the planar configuration of the imaging device according to the embodiment of the present disclosure.

FIG. 5C is a diagram illustrating an example of the planar configuration of the imaging device according to the embodiment of the present disclosure.

FIG. 6 is a diagram illustrating a configuration example of a structure of an imaging device according to a comparative example of the present disclosure.

FIG. 7 is a diagram illustrating an example of a phase delay amount in a light-guiding section of the imaging device according to the comparative example of the present disclosure.

FIG. 8 is a diagram illustrating a configuration example of a structure of the imaging device according to the embodiment of the present disclosure.

FIG. 9 is a diagram illustrating an example of a phase delay amount in a light-guiding section of the imaging device according to the embodiment of the present disclosure.

FIG. 10A is a diagram illustrating an example of a method of manufacturing the imaging device according to the embodiment of the present disclosure.

FIG. 10B is a diagram illustrating an example of the method of manufacturing the imaging device according to the embodiment of the present disclosure.

FIG. 10C is a diagram illustrating an example of the method of manufacturing the imaging device according to the embodiment of the present disclosure.

FIG. 10D is a diagram illustrating an example of the method of manufacturing the imaging device according to the embodiment of the present disclosure.

FIG. 10E is a diagram illustrating an example of the method of manufacturing the imaging device according to the embodiment of the present disclosure.

FIG. 10F is a diagram illustrating an example of the method of manufacturing the imaging device according to the embodiment of the present disclosure.

FIG. 10G is a diagram illustrating an example of the method of manufacturing the imaging device according to the embodiment of the present disclosure.

FIG. 11 is a diagram illustrating an example of a planar configuration of an imaging device according to Modification Example 1 of the present disclosure.

FIG. 12A is a diagram illustrating an example of a cross-sectional configuration of the imaging device according to Modification Example 1 of the present disclosure.

FIG. 12B is a diagram illustrating an example of the cross-sectional configuration of the imaging device according to Modification Example 1 of the present disclosure.

FIG. 13 is a diagram illustrating another example of the planar configuration of the imaging device according to Modification Example 1 of the present disclosure.

FIG. 14 is an explanatory diagram of a configuration example of a light-guiding section of an imaging device according to Modification Example 2 of the present disclosure.

FIG. 15 is an explanatory diagram of a configuration example of the light-guiding section of the imaging device according to Modification Example 2 of the present disclosure.

FIG. 16 is an explanatory diagram of a configuration example of a light-guiding section of an imaging device according to Modification Example 3 of the present disclosure.

FIG. 17 is an explanatory diagram of another configuration example of the light-guiding section of the imaging device according to Modification Example 3 of the present disclosure.

FIG. 18 is a diagram illustrating an example of a cross-sectional configuration of an imaging device according to Modification Example 4 of the present disclosure.

FIG. 19 is a block diagram illustrating a configuration example of an electronic apparatus including the imaging device.

FIG. 20 is a block diagram depicting an example of schematic configuration of a vehicle control system.

FIG. 21 is a diagram of assistance in explaining an example of installation positions of an outside-vehicle information detecting section and an imaging section.

FIG. 22 is a view depicting an example of a schematic configuration of an endoscopic surgery system.

FIG. 23 is a block diagram depicting an example of a functional configuration of a camera head and a camera control unit (CCU).

### DESCRIPTION OF EMBODIMENTS

Hereinafter, a description is given in detail of embodiments of the present disclosure with reference to the drawings. It is to be noted that the description is given in the following order.
1. Embodiment
2. Modification Examples
3. Application Example
4. Practical Application Examples

### 1. Embodiment

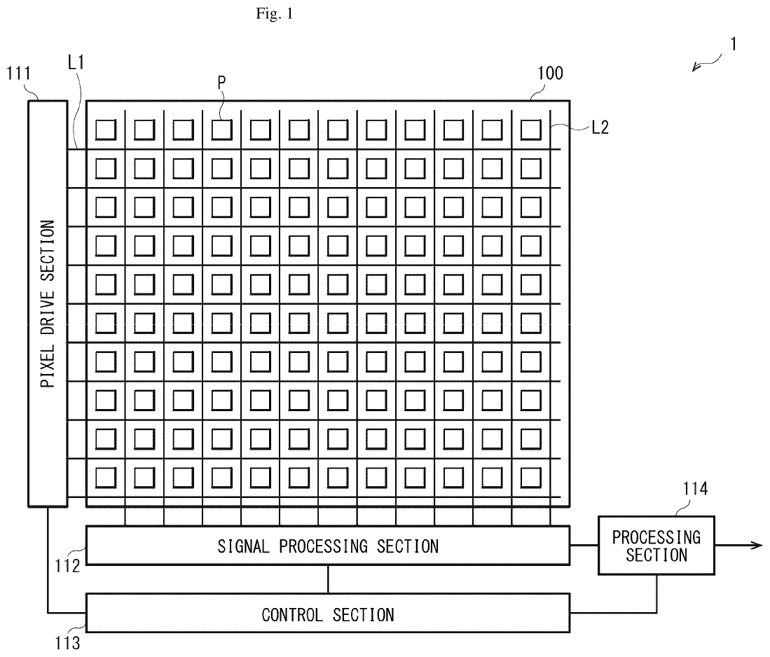

FIG. 1 is a block diagram illustrating an example of a schematic configuration of an imaging device which is an example of a photodetector according to an embodiment of the present disclosure. The photodetector is a device that is able to detect incoming light. An imaging device 1, which is a photodetector, includes a plurality of pixels P each including a photoelectric conversion section (photoelectric conversion element), and is configured to photoelectrically convert incident light and generate a signal. The imaging device 1 (photodetector) can receive light transmitted through an optical system including an optical lens and generate a signal.

The photoelectric conversion section of each of the pixels P of the imaging device 1 is, for example, a photodiode, and is configured to be able to photoelectrically convert light. The imaging device 1 includes, as an imaging area, a region (a pixel section 100) in which the plurality of pixels P are two-dimensionally arranged in matrix. The pixel section 100 can also be referred to as a pixel array in which the plurality of pixels P are arranged.

The imaging device 1 takes in incident light (image light) from a subject via the optical system (unillustrated) including the optical lens. The imaging device 1 captures an image of the subject formed by the optical lens. The imaging device 1 can photoelectrically convert received light to generate a pixel signal. The imaging device 1 is, for example, a CMOS (Complementary Metal Oxide Semiconductor) image sensor. The imaging device 1 is usable, for example, for an electronic apparatus such as a digital still camera, a video camera, or a mobile phone.

### Schematic Configuration of Imaging Device

As in the example illustrated in FIG. 1, the imaging device 1 includes, in a peripheral region of the pixel section 100 (pixel array), for example, a pixel drive section 111, a signal processing section 112, a control section 113, a processing section 114, and the like. In addition, the imaging device 1 is provided with a plurality of control lines L1 and a plurality of signal lines L2.

The control line L1 is a signal line that is able to transmit a signal to control the pixel P, and is coupled to the pixel drive section 111 and the pixels P of the pixel section 100. In the pixel section 100, in the example illustrated in FIG. 1, the plurality of control lines L1 are wired for respective pixel rows each configured by the plurality of pixels P arranged in a horizontal direction (row direction). The control line L1 is configured to transmit a control signal to read a signal from the pixel P.

As an example, the plurality of control lines L1 for respective pixel rows of the imaging device 1 includes a wiring line that transmits a signal to control a transfer transistor, a wiring line that transmits a signal to control a selection transistor, a wiring line that transmits a signal to control a reset transistor, and the like. The control line L1 can also be referred to as a drive line (pixel drive line) that transmits a signal to drive the pixel P.

The signal line L2 is a signal line that is able to transmit a signal from the pixel P, and is coupled to the pixels P of the pixel section 100 and the signal processing section 112. In the pixel section 100, for example, signal lines L2 are wired for respective pixel columns each configured by a plurality of pixels P arranged in a vertical direction (column direction). The signal line L2 is a vertical signal line, and is configured to transmit a signal outputted from the pixel P.

The pixel drive section 111 is configured to be able to drive each of the pixels P of the pixel section 100. The pixel drive section 111 is a drive circuit, and is configured by, for example, a plurality of circuits including a buffer, a shift register, an address decoder, and the like. The pixel drive section 111 generates a signal to drive the pixel P, and outputs the signal to each of the pixels P of the pixel section 100 via the control line L1. The pixel drive section 111 is controlled by the control section 113, and controls the pixels P of the pixel section 100.

The pixel drive section 111 generates, for example, a signal to the control the pixel P, such as a signal to control the transfer transistor of the pixel P and a signal to control the reset transistor, and supplies the signal to each of the pixels P by the control line L1. The pixel drive section 111 can perform control to read a pixel signal from each of the pixels P. The pixel drive section 111 can also be referred to as a pixel control section configured to be able to control each of the pixels P. It is to be noted that the pixel drive section 111 and the control section 113 can also be collectively referred to as a pixel control section.

The signal processing section 112 is configured to be able to execute signal processing of an inputted pixel signal. The signal processing section 112 is a signal processing circuit, and includes, for example, a load circuit part, an AD (Analog-to-Digital) converter part, a horizontal selection switch, and the like. It is to be noted that the signal processing section 112 may include an amplification circuit part configured to amplify a signal read from the pixel P via the signal line L2.

The signal output from each of the pixels P is selected and scanned by the pixel drive section 111 is input to the signal processing section 112 via the signal line L2. The signal processing section 112 can perform, for example, signal processing such as CDS (Correlated Double Sampling: correlated double sampling) and AD conversion of the signal of the pixel P. The signal of each of the pixels P transmitted through each of the signal lines L2 is subjected to signal processing by the signal processing section 112, and outputted to the processing section 114.

The processing section 114 is configured to be able to execute signal processing on an inputted signal. The processing section 114 is a signal processing circuit, and is configured by, for example, a circuit that performs various types of signal processing on a pixel signal. The processing section 114 may include a processor and a memory. The processing section 114 performs signal processing on the pixel signal input from the signal processing section 112, and outputs the processed pixel signal. The processing section 114 can perform, for example, various types of signal processing such as noise reduction processing or gradation correction processing.

The control section 113 is configured to be able to control each section of the imaging device 1. The control section 113 can receive a clock supplied from the outside, data ordering an operation mode, or the like, and output data such as internal information on the imaging device 1. The control section 113 is a control circuit, and includes, for example, a timing generator configured to be able to generate various timing signals. The control section 113 controls driving of the pixel drive section 111, the signal processing section 112, and the like on the basis of the various timing signals (pulse signals, clock signals, and the like) generated by the timing generator. It is to be noted that the control section 113 and the processing section 114 may be integrally configured.

The pixel drive section 111, the signal processing section 112, the control section 113, the processing section 114, and the like may be provided in one semiconductor substrate or may be provided separately in a plurality of semiconductor substrates. The imaging device 1 may have a structure (stacked structure) configured by stacking a plurality of substrates.

### Configuration of Pixel

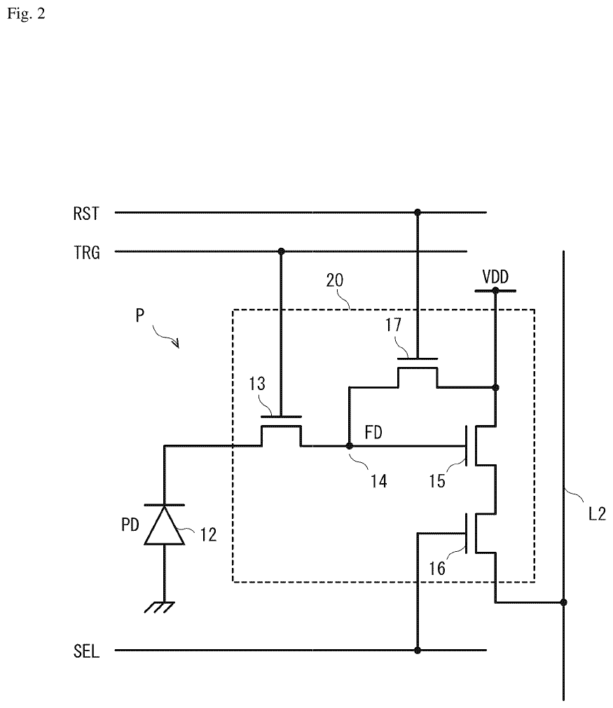

FIG. 2 is a diagram illustrating a configuration example of a pixel of an imaging device according to the embodiment. The pixel P includes a photoelectric conversion section 12 (photoelectric conversion element) and a readout circuit 20. The readout circuit 20 is configured to be able to output a signal based on electric charge having undergone photoelectric conversion. As an example, the readout circuit 20 includes a transfer transistor 13, an FD (floating diffusion) 14, an amplification transistor 15, a selection transistor 16, and a reset transistor 17.

The transfer transistor 13, the amplification transistor 15, the selection transistor 16, and the reset transistor 17 are each an MOS transistor (MOSFET) including terminals of a gate, a source, and a drain. In the example illustrated in FIG. 2, the transfer transistor 13, the amplification transistor 15, the selection transistor 16, and the reset transistor 17 are each configured by an NMOS transistor. It is to be noted that the transistor of the pixel P may be configured by a PMOS transistor.

The photoelectric conversion section 12 is configured to receive light and generate a signal. The photoelectric conversion section 12 is a light-receiving section (light-receiving element), and is configured to be able to generate electric charge by photoelectric conversion. In the example illustrated in FIG. 2, the photoelectric conversion section 12 is a photodiode (PD), and converts incoming light into electric charge. The photoelectric conversion section 12 performs photoelectric conversion to generate electric charge corresponding to a received light amount.

The transfer transistor 13 is configured to be able to transfer the electric charge photoelectrically converted by the photoelectric conversion section 12 to the FD 14. As illustrated in FIG. 2, the transfer transistor 13 is controlled by a signal TRG to electrically couple or decouple the photoelectric conversion section 12 and the FD 14 to or from each other. The transfer transistor 13 can transfer electric charge photoelectrically converted and accumulated by the photoelectric conversion section 12 to the FD 14.

The FD 14 is an accumulation section, and is configured to be able to accumulate the transferred electric charge. The FD 14 can accumulate electric charge photoelectrically converted by the photoelectric conversion section 12. The FD 14 can also be referred to as a holding section that is able to hold the transferred electric charge. The FD 14 accumulates and converts the transferred electric charge into a voltage corresponding to a capacity of the FD 14.

The amplification transistor 15 is configured to generate and output a signal based on the electric charge accumulated in the FD 14. As illustrated in FIG. 2, a gate of the amplification transistor 15 is electrically coupled to the FD 14 to allow the voltage converted by the FD 14 to be input thereto. A drain of the amplification transistor 15 is coupled to a power supply line to be supplied with a power supply voltage VDD, and a source of the amplification transistor 15 is coupled to the signal line L2 via the selection transistor 16. The amplification transistor 15 can generate a signal based on the electric charge accumulated in the FD 14, i.e., a signal based on the voltage of the FD 14, and output the generated signal to the signal line L2.

The selection transistor 16 is configured to be able to control the output of a pixel signal. The selection transistor 16 is controlled by a signal SEL, and is configured to be able to output the signal from the amplification transistor 15 to the signal line L2. The selection transistor 16 can control an output timing of the pixel signal. It is to be noted that the selection transistor 16 may be provided between the power supply line to be supplied with the power supply voltage VDD and the amplification transistor 15. In addition, the selection transistor 16 may be omitted, as needed.

The reset transistor 17 is configured to be able to reset the voltage of the FD 14. In the example illustrated in FIG. 2, the reset transistor 17 is electrically coupled to the power supply line to be supplied with the power supply voltage VDD, and is configured to reset electric charge of the pixel P. The reset transistor 17 can be controlled by a signal RST to reset the electric charge accumulated in the FD 14 and to reset the voltage of the FD 14. It is to be noted that the reset transistor 17 can discharge the electric charge accumulated in the photoelectric conversion section 12 via the transfer transistor 13.

The pixel drive section 111 (see FIG. 1) supplies a control signal to the gates of the transfer transistor 13, the selection transistor 16, the reset transistor 17, and the like of each of the pixels P via the above-described control line L1, to bring the transistors into an ON state (an electrically-conductive state) or an OFF state (a non-electrically-conductive state). The plurality of control lines L1 of the imaging device 1 includes a wiring line that transmits the signal TRG to control the transfer transistor 13, a wiring line that transmits the signal SEL to control the selection transistor 16, a wiring line that transmits the signal RST to control the reset transistor 17, and the like.

The transfer transistor 13, the selection transistor 16, the reset transistor 17, and the like are controlled to be turned ON or OFF by the pixel drive section 111. The pixel drive section 111 controls the readout circuit 20 of each of the pixels P to thereby cause each of the pixels P to output a pixel signal to the signal line L2. The pixel drive section 111 can perform control to read the pixel signal of each of the pixels P to the signal line L2.

### Configuration of Imaging Device

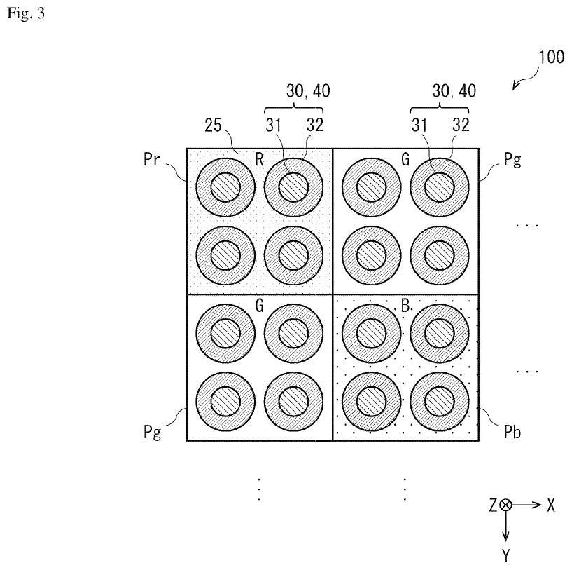

FIG. 3 is a diagram illustrating an example of a planar configuration of the imaging device according to the embodiment. FIG. 3 illustrates an example of an arrangement of the pixels P of the pixel section 100 in the imaging device 1. The pixel P of the imaging device 1 includes a filter 25. In addition, the pixel P includes a light-guiding section 40 (light-guiding member) configured using a structure 30, as described later. It is to be noted that, as illustrated in FIG. 3, a direction in which light from the subject is incident is defined as a Z-axis direction; a right-left direction on the sheet orthogonal to the Z-axis direction is defined as an X-axis direction; and an up-down direction on the sheet orthogonal to the Z-axis direction and the X-axis direction is defined as a Y-axis direction. In the following drawings, the arrow directions in FIG. 3 may be used, in some cases, as a standard to express a direction.

The filter 25 is configured to selectively transmit light of a particular wavelength region of the incoming light. The filter 25 is, for example, a color filter of RGB, a filter that transmits infrared light, or the like. The plurality of pixels P provided in the pixel section 100 of the imaging device 1 includes a plurality of pixels Pr provided with the filter 25 that transmits red (R) light, a plurality of pixels Pg provided with the filter 25 that transmits green (G) light, and a plurality of pixels Pb provided with the filter 25 that transmits blue (B) light.

In the pixel section 100, as in the example illustrated in FIG. 3, the plurality of pixels Pr, the plurality of pixels Pg, and the plurality of pixels Pb are repeatedly arranged. The pixel Pr, the pixel Pg, and the pixel Pb are arranged in accordance with Bayer arrangement, for example. The pixel Pr, the pixel Pg, and the pixel Pb generate a pixel signal of an R component, a pixel signal of a G component, and a pixel signal of a B component, respectively. The imaging device 1 is able to obtain pixel signals of RGB.

It is to be noted that the filter 25 provided for the pixels P of the pixel section 100 is not limited to a color filter of a primary color system (RGB), and may be a color filter of a complementary color system such as Cy (cyan), Mg (magenta), or Ye (yellow), for example. A filter corresponding to W (white), i.e., a filter that transmits light beams of all wavelength regions of incident light may be arranged.

In addition, the filter 25 may be omitted, as needed, in the imaging device 1. For example, in the pixel P that receives white (W) light to perform photoelectric conversion, the filter 25 may not be provided. In addition, for example, depending on characteristics of the light-guiding section 40, the filter 25 may not be provided for some or all of the pixels P of the imaging device 1.

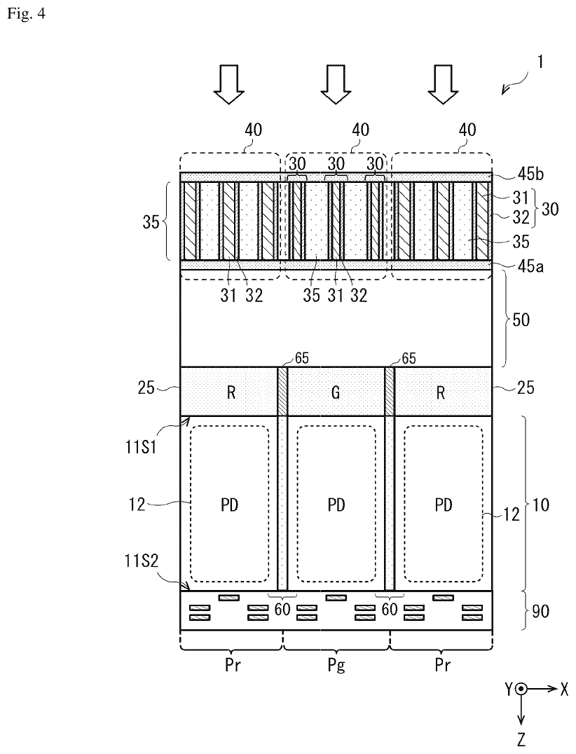

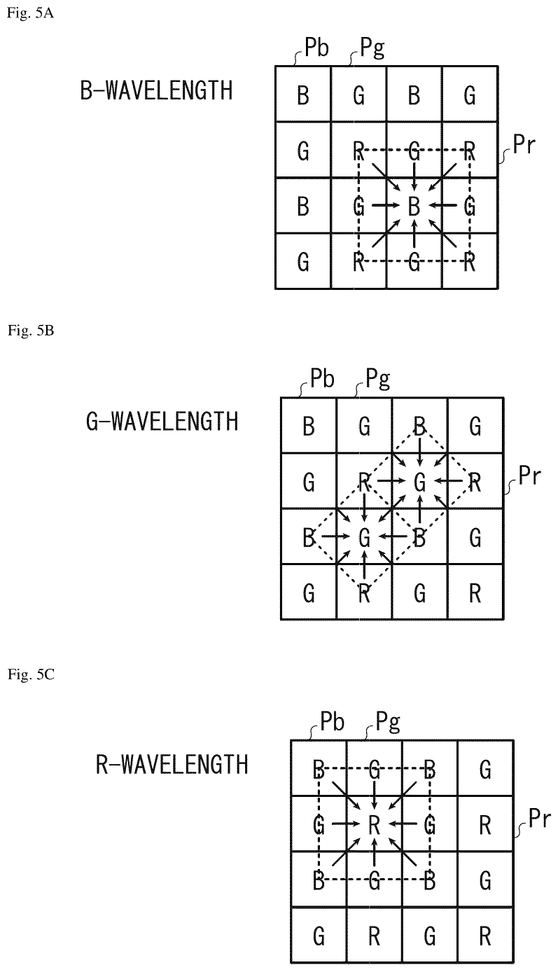

FIG. 4 is a diagram illustrating an example of a cross-sectional configuration of the imaging device according to the embodiment. FIGS. 5A to 5C are each a diagram illustrating an example of a planar configuration of the imaging device according to the embodiment. As illustrated in FIG. 4, the imaging device 1 has a configuration in which, for example, the light-guiding section 40, an insulating layer 50, the filter 25, a semiconductor layer 10, and a multilayer wiring layer 90 are stacked in the Z-axis direction.

As illustrated in FIG. 4, the semiconductor layer 10 has a first surface 11S1 and a second surface 11S2 opposed to each other. The second surface 11S2 is a surface on a side opposite to the first surface 11S1. The semiconductor layer 10 is configured by a semiconductor substrate, e.g., a Si (silicone) substrate. The first surface 11S1 of the semiconductor layer 10 is light-receiving surface (light incident surface). The second surface 11S2 of the semiconductor layer 10 is an element formation surface on which an element such as a transistor is formed. The second surface 11S2 of the semiconductor layer 10 can be provided with a gate electrode, a gate oxide film, and the like.

In the example illustrated in FIG. 4, the filter 25, the light-guiding section 40, and the like are provided on a side of the first surface 11S1 of the semiconductor layer 10. The multilayer wiring layer 90 is provided on a side of the second surface 11S2 of the semiconductor layer 10. The light-guiding section 40, the filter 25, and the like are provided on a side on which light from an optical system is incident, and the multilayer wiring layer 90 is provided on a side opposite to the side on which light is incident.

The imaging device 1 is a so-called back-illuminated imaging device.

In the semiconductor layer 10, a plurality of photoelectric conversion sections 12 (photoelectric conversion elements) are provided along the first surface 11S1 and the second surface 11S2 of the semiconductor layer 10. For example, the plurality of photoelectric conversion sections 12 are embedded and formed in the semiconductor layer 10. It is to be noted that the semiconductor layer 10 may be an SOI (Silicon On Insulator) substrate, an SiGe (silicon germanium) substrate, an SiC (silicon carbide) substrate, or the like, and may be configured by a Group III-V compound semiconductor material, or the like.

The multilayer wiring layer 90 includes, for example, a conductor film and an insulating film, and includes a plurality of wiring line, vias (VIA), and the like. The multilayer wiring layer 90 includes, for example, two or more layers of wiring lines.

The multilayer wiring layer 90 has a configuration in which a plurality of wiring lines are stacked with the insulating film interposed therebetween. The insulating film of the multilayer wiring layer 90 can also be referred to as an interlayer insulating film (interlayer insulating layer).

The wiring line of the multilayer wiring layer 90 is formed using a metal material such as aluminum (Al), copper (Cu), or tungsten (W). The wiring line of the multilayer wiring layer 90 may be configured using polysilicon (Poly-Si) or another electrically-conductive material. The interlayer insulating film is formed using, for example, silicon oxide (SiO), silicon nitride (SiN), silicon oxynitride (SiON), or the like.

The semiconductor layer 10 and the multilayer wiring layer 90 are provided with, for example, the above-described readout circuit 20 (see FIG. 2). It is to be noted that the pixel drive section 111, the signal processing section 112, the control section 113, the processing section 114, and the like described above can be provided in a substrate different from the semiconductor layer 10, or in the semiconductor layer 10 and the multilayer wiring layer 90.

The insulating layer 50 is provided between a layer provided with the light-guiding section 40 and a layer provided with the filter 25. The insulating layer 50 is a spacer layer, and is provided to be stacked on the filter 25 between the light-guiding section 40 and the semiconductor layer 10, and is positioned on the first surface 11S1 of the semiconductor layer 10. The insulating layer 50 is formed using, for example, an insulating film such as an oxide film, a nitride film, or an oxynitride film.

The insulating layer 50 may be configured by silicon oxide (SiO), silicon nitride (SiN), silicon oxynitride (SiON), and the like, or may be configured using another insulating material. The insulating layer 50 can also be referred to as a planarization layer (planarization film). In addition, the insulating layer 50 can also be referred to as a transparent layer that transmits light.

In addition, the imaging device 1 is provided with a separation section 60, a light-guiding wall 65, and an antireflection film 45a. The separation section 60 is provided between the plurality of photoelectric conversion sections 12 adjacent to each other to separate the photoelectric conversion sections 12 from each other. The separation section 60 has a trench (groove) provided at a boundary between the pixels P (or the photoelectric conversion sections 12) adjacent to each other. The separation section 60 is provided to surround the photoelectric conversion section 12 in the semiconductor layer 10, for example.

The separation section 60 can be provided to penetrate the semiconductor layer 10, for example, as in the example illustrated in FIG. 4. As an example, an insulating film, e.g., a silicone oxide film is provided inside the trench of the separation section 60. It is to be noted that polysilicon, a metal material, or the like may be embedded in the trench of the separation section 60. The separation section 60 may be formed using another dielectric material having a low refractive index. For example, an air gap (cavity) may be provided inside the trench of the separation section 60. Providing the separation section 60 suppresses leakage of light to surrounding pixels P.

The light-guiding wall 65 is provided between a plurality of filters 25 adjacent to each other. The light-guiding wall 65 is, for example, a wall-shaped structure, and is provided to surround four sides of the filter 25. The light-guiding wall 65 is positioned at the sides of the filter 25, and has a refractive index lower than a refractive index of a surrounding medium. The light-guiding wall 65 has a refractive index lower than a refractive index of the filter 25. The light-guiding wall 65 is provided at a boundary between the pixels P adjacent to each other, and can also be referred to as a separation wall (or separation section) that separates the filters 25 from each other.

The light-guiding wall 65 is configured by, for example, silicon oxide, air gap (cavity), or the like. It is to be noted that the light-guiding wall 65 may be formed using another dielectric material having a low refractive index. The light-guiding wall 65 may be configured using an organic material. The light-guiding wall 65 changes a direction in which incident light travels by a refractive index difference between the light-guiding wall 65 and the surrounding medium. Providing the light-guiding wall 65 suppresses light leakage into surrounding pixels P, thus reducing color mixture.

It is to be noted that the imaging device 1 may include a fixed charge film. The fixed charge film is provided between the semiconductor layer 10 and the filter 25, for example. As an example, the fixed charge film is configured by a metal compound (metal oxide, metal nitride, etc.). The fixed charge film is, for example, a film having negative fixed electric charge, and suppresses generation of a dark current at an interface of the semiconductor layer 10.

The antireflection film 45a is configured using, for example, an insulating material such as silicon nitride (SiN) or silicon oxide (SiO). In the example illustrated in FIG. 4, the antireflection film 45a is provided on the insulating layer 50 to reduce (suppress) reflection. It is to be noted that the insulating layer 50 or the light-guiding section 40 may include the antireflection film 45a.

The light-guiding section 40 (light-guiding member) includes the structure 30, and is configured to guide incident light to a side of the photoelectric conversion section 12. Light from a subject to be measured is incident on the light-guiding section 40. The structure 30 is a fine (minute) structure having a size equal to or less than a predetermined wavelength of incoming light. The structure 30 has, for example, a size (e.g., width) equal to or less than a wavelength of visible light. The structure 30 may have a size equal to or less than a wavelength of infrared light.

The light-guiding section 40 includes the structure 30 and a filling material 35 provided around the structure 30. The structure 30 is configured using a plurality of materials, and has a columnar (pillar) shape. In the example illustrated in FIG. 4, the structure 30 includes a first member 31 and a second member 32 provided around the first member 31. The second member 32 is provided to surround the first member 31. The second member 32 is formed to cover, for example, a side surface (side part) of the first member 31. The structure 30 may be provided above the photoelectric conversion element 12 and disperses incident light

The filling material 35 is provided to fill between the structures 30 adjacent to each other. The filling material 35 is embedded between a plurality of structures 30. It is to be noted that the filling material 35 may be formed to cover the structure 30 including the first member 31 and the second member 32. The first member 31 and the second member 32 are provided inside the filling material 35, and can be referred to as being arranged to replace a portion of the filling material 35.

In addition, as illustrated in FIG. 4, the light-guiding section 40 includes an antireflection film 45b. The antireflection film 45b is configured by, for example, an insulating material such as silicon oxide (SiO) or silicon nitride (SiN). It is to be noted that the antireflection film 45b may be configured using silicon oxynitride (SiON) or may be configured by another material. The antireflection film 45b is provided on the structure 30 to reduce (suppress) reflection. The antireflection film 45b is provided to cover, for example, the structure 30 and the filling material 35.

The light-guiding section 40 is an optical element utilizing a metamaterial (metasurface) technology, and can also be referred to as a light-guiding element that is able to guide light. As described later, the light-guiding section 40 according to the present embodiment is also a light-dispersing section (light-dispersing element), and is configured to disperse incoming light. The light-guiding section 40 can be provided for each pixel P or for each plurality of pixels P, for example.

The structure 30 is, for example, a columnar (pillar-shaped) structure, as illustrated in FIG. 4. As schematically illustrated in FIG. 4, the plurality of structures 30 are arranged side by side in the right-left direction (X-axis direction) on the sheet, with a portion of the filling material 35 interposed therebetween. In each of the pixels P, the plurality of structures 30 can be arranged at an interval equal to or less than a predetermined wavelength of incident light, e.g., at an interval equal to or less than a wavelength of visible light (or infrared light).

The structure 30 has a refractive index different from a refractive index of an adjacent medium. In the example illustrated in FIG. 4, the first member 31 of the structure 30 has a refractive index different from a refractive index of the second member 32 arranged around the first member 31. The second member 32 of the structure 30 has a refractive index different from a refractive index of the filling material 35.

The first member 31 of the structure 30 may have a refractive index higher than the refractive index of the second member 32, for example. In addition, the first member 31 may have a refractive index higher than the refractive index of the filling material 35. The first member 31 can be configured by a material having a refractive index higher than the refractive index of the second member 32 and the refractive index of the filling material 35.

The second member 32 of the structure 30 has, for example, a refractive index different from the refractive index of the filling material 35 and the refractive index of the first member 31 arranged around the second member 32. As an example, the second member 32 is configured by a material having a refractive index higher than the refractive index of the filling material 35, and has a refractive index higher than the refractive index of the filling material 35. In addition, for example, the second member 32 is configured by a material having a refractive index lower than the refractive index of the filling material 35, and has a refractive index lower than the refractive index of the filling material 35.

A difference between the refractive index of the first member 31 and the refractive index of the second member 32 is, for example, 1.0 or more. In addition, for example, the difference between the refractive index of the first member 31 and the refractive index of the second member 32 may be 1.2 or more, or maybe 1.5 or more. It is to be noted the difference between the refractive index of the first member 31 and the refractive index of the second member 32 may be 0.3 or more.

The difference between the refractive index of the second member 32 and the refractive index of the filling material 35 is, for example, 1.0 or more. In addition, for example, the difference between the refractive index of the second member 32 and the refractive index of the filling material 35 may be 1.2 or more, or maybe 1.5 or more. It is to be noted that the difference between the refractive index of the second member 32 and the refractive index of the filling material 35 may be 0.3 or more.

As an example, the structure 30 is configured using titanium oxide. The structure 30 may be configured by a simple substance, oxide, nitride, oxynitride, or composite of titanium, hafnium, zirconium, tantalum, aluminum, niobium, indium, and the like. In addition, the structure 30 may be formed using silicon oxide, silicon nitride, silicon nitride oxide, silicon carbide, silicon oxide carbide, or another silicon compound. The structure 30 may be formed using amorphous silicon (a-Si), polysilicon, germanium (Ge), or the like.

In addition, the structure 30 may be configured from an organic matter such as siloxane. For example, the structure 30 may be configured using a siloxane-based resin, a styrene-based resin, an acrylic-based resin, or the like. The structure 30 may be configured by a material containing fluorine in any of these resins. The structure 30 may be formed using a material in which any of these resins is filled with beads (filler) having a refractive index higher than that of the resin.

As described above, the first member 31 and the second member 32 of the structure 30 may be configured using an inorganic material, or may be configured using an organic material. For example, the first member 31 may be configured by a metal compound (metal oxide, metal nitride, etc.) such as titanium oxide. The first member 31 and the second member 32 may be configured using different materials, or may be configured using the same type of materials.

As an example, the filling material 35 is formed using an inorganic material such as an oxide, a nitride, or an oxynitride. The filling material 35 is configured by, for example, silicon oxide, silicon nitride, silicon nitride oxide, silicon carbide, silicon oxide carbide, or the like. It is to be noted that the filling material 35 may be configured using an organic material. The filling material 35 may be configured using a siloxane-based resin, a styrene-based resin, an acrylic-based resin, or the like. The filling material 35 may be configured by a material containing fluorine in any of these resins. The filling material 35 may be formed using a material in which any of these resins is filled with beads having a refractive index higher than that of the resin.

Materials of the first member 31, the second member 32, and the filling material 35 can be selected depending on a refractive index difference from the surrounding medium as well as a wavelength region of incident light to be measured. It is to be noted that the first member 31, the second member 32, and the filling material 35 may be partially configured using air (air gap). That is, the light-guiding section 40 may have a space (cavity).

The light-guiding section 40 causes a phase delay in incoming light due to the refractive index difference between the structure 30 and the surrounding medium, thus making it possible to exert an influence on a wave front. The light-guiding section 40 provides a different phase delay amount depending on a wavelength of light, thereby making it possible to adjust a direction in which light propagates and thus to separate incident light into light beams of respective wavelength regions.

A size (size), shape, refractive index, pitch (arrangement interval), and the like of each of the structures 30 are determined to allow the light beams of the respective wavelength regions included in the incident light to travel in desired directions. In the example illustrated in FIG. 4, the size (width, height, etc.), shape, refractive index, and pitch of each of the first member 31 and the second member 32 of the structure 30 and the refractive index and the like of the filling material 35 can be adjusted.

The light-guiding section 40 (light-dispersing section) is a light-dispersing element that is able to disperse light utilizing a metamaterial (metasurface) technology, and can also be referred to as a splitter (color splitter). The imaging device 1 according to the present embodiment can also be referred to as having a color splitter structure.

The directions in which the light-guiding section 40 propagates light beams of respective wavelengths are adjustable by materials (optical constants) of the first member 31, the second member 32, the filling material 35, and the like, and the shape, height, arrangement position, and the like of the structure 30. The light-guiding section 40 is a light-dispersing section configured to be able to disperse incident light. It is to be noted that each light-guiding section 40 of the imaging device 1 can also be referred to as a region (light-dispersing region) that disperses incident light by the structure 30.

The light-guiding section 40 provides respective different phase delays to light beams of a plurality of wavelength regions, e.g., light beams of a first wavelength region to a third wavelength region. This enables, in the imaging device 1, light incident on the light-guiding section 40 to be split into light of the first wavelength region (e.g., light of a blue wavelength region), light of the second wavelength region (e.g., light of a green wavelength region), and light of the third wavelength region (e.g., light of a red wavelength region). The imaging device 1 can adjust a traveling direction of each of blue light, green light, and red light, for example.

The light-guiding section 40 of the pixel Pb is configured to propagate blue (B) light, of incoming light, to the filter 25 and the photoelectric conversion section 12 of the pixel Pb and to propagate red (R) light to the filter 25 and the photoelectric conversion section 12 of the pixel Pr. The light-guiding section 40 of the pixel Pb splits incident light, and guides light of the red wavelength region, of the incident light, toward the pixel Pr.

In addition, the light-guiding section 40 of the pixel Pb is configured to propagate green (G) light, of incoming light, to the filter 25 and the photoelectric conversion section 12 of the pixel Pg. The light-guiding section 40 of the pixel Pb splits incident light, and guides light of the green wavelength region, of the incident light, toward the pixel Pg.

The light-guiding section 40 of the pixel Pr is configured to propagate red (R) light, of incoming light, to the filter 25 and the photoelectric conversion section 12 of the pixel Pr and to propagate blue (B) light to the filter 25 and the photoelectric conversion section 12 of the pixel Pb. The light-guiding section 40 of the pixel Pr splits incident light, and guides light of the blue wavelength region, of the incident light, toward the pixel Pb.

In addition, the light-guiding section 40 of the pixel Pr is configured to propagate green (G) light, of incoming light, to the filter 25 and the photoelectric conversion section 12 of the pixel Pg. The light-guiding section 40 of the pixel Pr splits incident light, and guides light of the green wavelength region, of the incident light, toward the pixel Pg.

The light-guiding section 40 of the pixel Pg is configured to propagate green (G) light, of incoming light, to the filter 25 and the photoelectric conversion section 12 of the pixel Pg and to propagate blue (B) light to the filter 25 and the photoelectric conversion section 12 of the pixel Pb. The light-guiding section 40 of the pixel Pg splits incident light, and guides light of the blue wavelength region, of the incident light, toward the pixel Pb.

In addition, the light-guiding section 40 of the pixel Pg is configured to propagate red (R) light, of incoming light, to the filter 25 and the photoelectric conversion section 12 of the pixel Pr. The light-guiding section 40 of the pixel Pg splits incident light, and guides light of the red wavelength region, of the incident light, toward the pixel Pr.

Thus, as schematically illustrated by arrows in FIG. 5A, a plurality of pixels surrounding the pixel Pb guides light of the blue wavelength, of incident light, toward the pixel Pb. Blue light incident on the pixel Pb and blue light incident on each of the pixels around the pixel Pb are able to be condensed on the filter 25 and the photoelectric conversion section 12 of the pixel Pb. It is possible for the photoelectric conversion section 12 of the pixel Pb to efficiently receive light of the blue wavelength region and perform photoelectric conversion to generate electric charge corresponding to a received light amount.

As schematically illustrated by arrows in FIG. 5B a plurality of pixels surrounding the pixel Pg guides light of the green wavelength, of incident light, toward the pixel Pg. Green light incident on the pixel Pg and green light incident on each of the pixels around the pixel Pg are able to be condensed on the filter 25 and the photoelectric conversion section 12 of the pixel Pg. It is possible for the photoelectric conversion section 12 of the pixel Pg to efficiently receive light of the green wavelength region and perform photoelectric conversion to generate electric charge corresponding to a received light amount.

In addition, as schematically illustrated by arrows in FIG. 5C, a plurality of pixels surrounding the pixel Pr guides light of the red wavelength, of incident light, toward the pixel Pr. Red light incident on the pixel Pr and red light incident on each of the pixels around the pixel Pr are able to be condensed on the filter 25 and the photoelectric conversion section 12 of the pixel Pr. It is possible for the photoelectric conversion section 12 of the pixel Pr to efficiently receive light of the red wavelength region and perform photoelectric conversion to generate electric charge corresponding to a received light amount.

In this manner, the imaging device 1 is able to take more light effectively into the pixel P, thus making it possible to improve quantum efficiency (QE). It is to be noted that the structures 30 of the respective light-guiding sections 40 of the above-described pixel Pb, pixel Pg, and pixel Pr can be formed to have respective different sizes (e.g., widths), shapes, and the like, for example.

As described above, light from a subject is incident on the photoelectric conversion section 12 of each of the pixels P via the light-guiding section 40, the filter 25, and the like. The photoelectric conversion section 12 can receive the light incident via the structure 30 of the light-guiding section 40 and perform photoelectric conversion to generate electric charge corresponding to a received light amount. Thus, the imaging device 1 uses a pixel signal to be obtained by means of the photoelectric conversion by the photoelectric conversion section 12 to enable generation of a visible image, an infrared image, or the like, for example. It is possible, in the imaging device 1, to cause the light-guiding section 40 to appropriately condense the light, thus making it possible to improve sensitivity to incident light.

In the present embodiment, as described above, the structure 30 of the light-guiding section 40 is configured using the first member 31 and the second member 32. It is therefore possible to finely adjust a phase delay amount of light of each of the wavelength regions by setting an average refractive index of the light-guiding sections 40, thus making it possible to achieve a distribution of a desired phase delay amount. This reduces a difference between an ideal phase distribution for implementing the color splitter and an actual phase distribution, thus making it possible to appropriately condense light. It is possible to improve sensitivity to incident light. Hereinafter, a description is further given of the imaging device 1 according to the present embodiment in comparison with a comparative example.

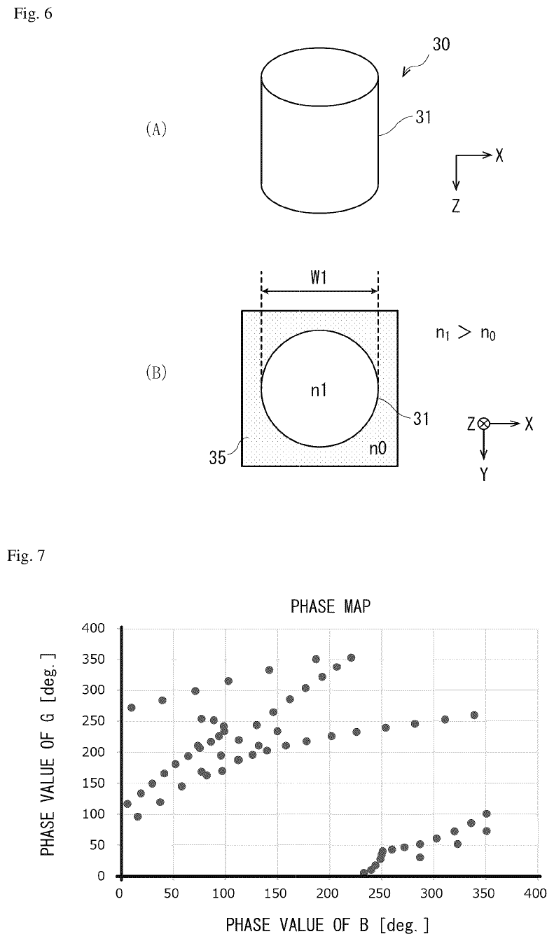

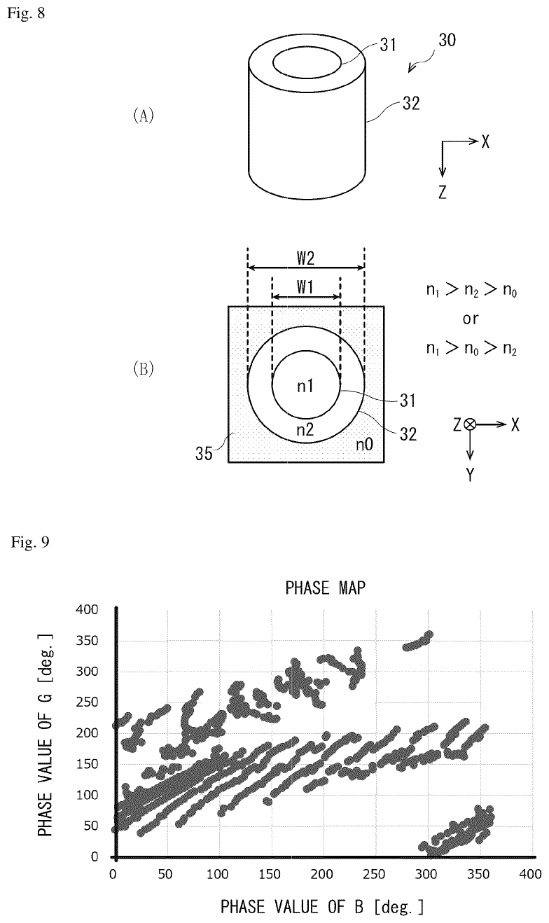

FIG. 6 is a diagram illustrating a configuration example of a structure of an imaging device according to the comparative example. FIG. 7 is a diagram illustrating an example of a phase delay amount in a light-guiding section of the imaging device according to the comparative example. The comparative example concerns a case where the structure 30 includes no second member 32. The structure 30 according to the comparative example is configured by one first member 31. The first member 31 has a refractive index of n1, and the filling material 35 has a refractive index of n0.

In FIG. 7, the vertical axis indicates a phase delay amount (unit: deg) of green light, and the horizontal axis indicates a phase delay amount of blue light. FIG. 7 illustrates a phase delay amount in a case where a width W1 of the first member 31 is changed, provided that n1>n0 holds true. It is to be noted that the width W1 is a width (length) in a direction orthogonal to a direction in which light from a subject is incident (i.e., a stacking direction of the light-guiding section 40 and the semiconductor layer 10 (Z-axis direction)).

In the comparative example, as in the example illustrated in FIG. 7, only changing the width W1 of the first member 31 results in limitation of the number of possible combinations of phase values which can be adopted by light beams of three wavelengths of RGB. In this case, it is conceivable that the difference between the ideal phase distribution for implementing the color splitter and the actual phase distribution may be increased. This makes it difficult to ideally condense light, which may possibly cause deterioration in an effect of improving sensitivity.

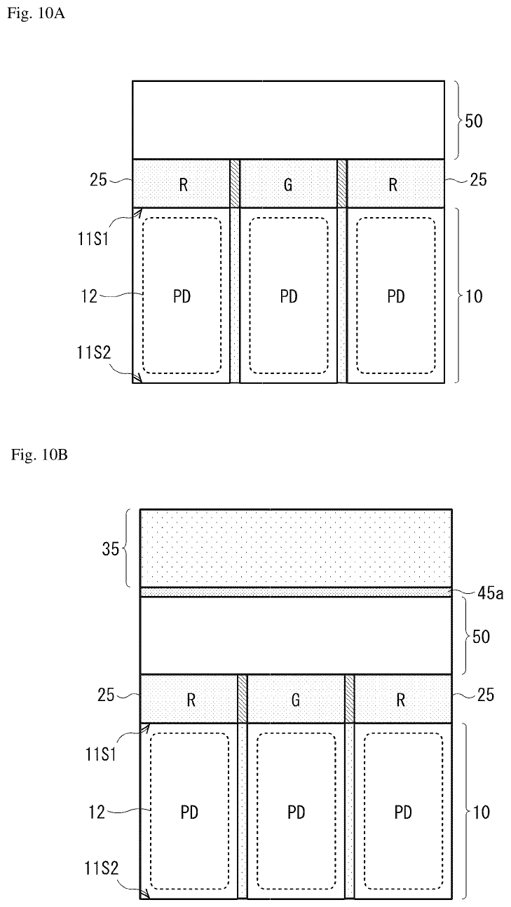

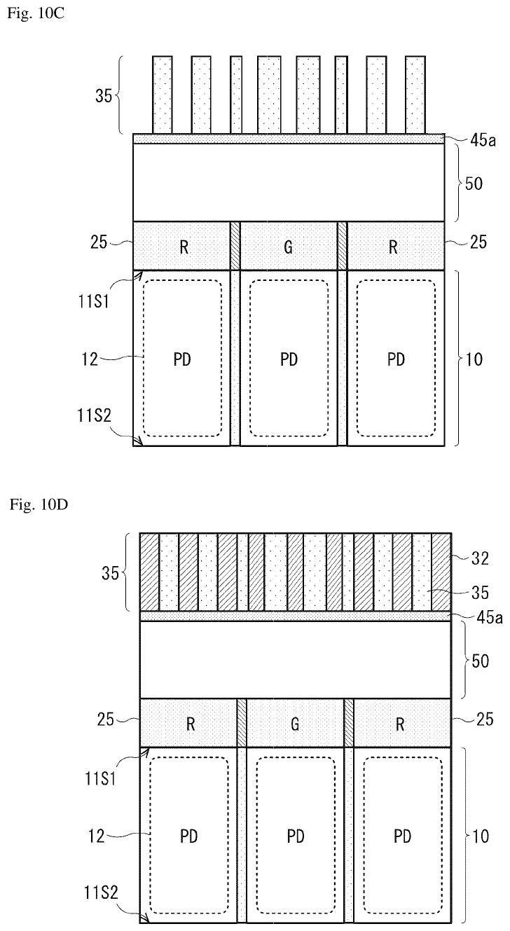

FIG. 8 is a diagram illustrating a configuration example of the structure of the imaging device according to the embodiment. FIG. 9 is a diagram illustrating an example of a phase delay amount in the light-guiding section of the imaging device according to the embodiment. As in the example illustrated in FIG. 8, the structure 30 according to the present embodiment is configured using the first member 31 and the second member 32 described above. The first member 31 has a refractive index of n1, and the second member 32 has a refractive index of n2. In addition, the filling material 35 has a refractive index of n0.

FIG. 9 illustrates a phase delay amount in a case where the width W1 of the first member 31 and a width W2 of the second member 32 are each changed, provided that n1>n0>n2 holds true. It is to be noted that the widths W1 and W2 are each a width (length) in a direction orthogonal to the direction in which light from a subject is incident (i.e., the stacking direction of the light-guiding section 40 and the semiconductor layer 10 (Z-axis direction)).

In the present embodiment, as in the example illustrated in FIG. 9, it is possible to increase the number of possible combinations of phase values which can be adopted by light beams of three wavelengths of RGB. Therefore, it is possible to reduce the difference between the ideal phase distribution for implementing the color splitter and the actual phase distribution. This makes it possible for the imaging device 1 to appropriately condense incoming light and thus to improve sensitivity to incident light.

The first member 31, the second member 32, and the filling material 35 may be provided to satisfy n1>n0>n2. In addition, the first member 31, the second member 32, and the filling material 35 may be provided to satisfy n1>n2>n0. It is possible to efficiently condense light onto the photoelectric conversion section 12 and thus to improve quantum efficiency (QE). It is possible to prevent deterioration in spectral characteristics.

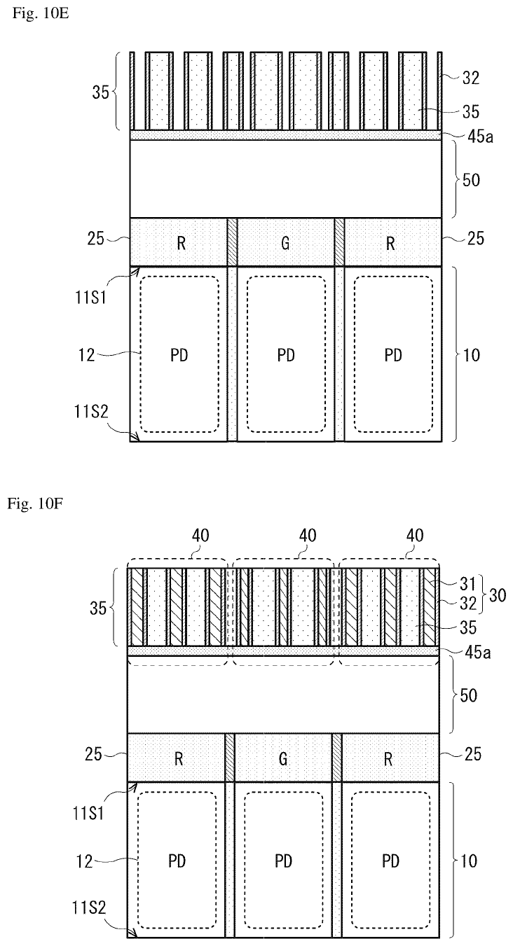

FIGS. 10A to 10G are each a diagram illustrating an example of a method of manufacturing the imaging device according to the embodiment. First, as illustrated in FIG. 10A, the insulating layer 50, which is a spacer layer, is formed as a film over the semiconductor layer 10 in which and on which the photoelectric conversion section 12, the filter 25, and the like are formed. Then, as illustrated in FIG. 10B, the antireflection film 45a and the filling material 35 are formed on the insulating layer 50.

Next, the filling material 35 is selectively removed by lithography and etching, and a plurality of holes (holes) are formed in the filling material 35, as illustrated in FIG. 10C. Then, as illustrated in FIG. 10D, the second member 32 is embedded and formed in each of the holes of the filling material 35.

Next, the second member 32 is selectively removed by lithography and etching, and holes are formed in the second member 32, as illustrated in FIG. 10E. Then, as illustrated in FIG. 10F, the first member 31 is embedded and formed in the hole of the second member 32. Further, as illustrated in FIG. 10G, the antireflection film 45b is formed. Thereafter, the filter 25 and the like are formed. Through the manufacturing method as described above, the imaging device 1 illustrated in FIG. 4 or other drawings is able to be manufactured. It is to be noted that the above-described manufacturing method is merely exemplary, and another manufacturing method may be employed.

### Workings and Effects

The optical element according to the present embodiment includes a structure (structure 30) having a columnar shape and including a first member (first member 31) and a second member (second member 32) provided around the first member and having a refractive index different from a refractive index of the first member, and a filling material (filling member 35) provided around the structure and having a refractive index different from the refractive index of the second member.

The optical element (light-guiding section 40) according to the present embodiment includes the columnar structure 30 including the first member 31 and the second member 32, and the filling material 35. Therefore, it is possible to appropriately condense incoming light. It is possible to implement an optical element that is able to efficiently condense light.

The photodetector according to the present embodiment includes a first light-guiding member (light-guiding section 40) including a first structure (structure 30) having a columnar shape and the filling material (filling member 35) provided around the first structure, and a first photoelectric conversion element (photoelectric conversion section 12) that photoelectrically converts light incident via the first light-guiding member. The first structure includes the first member (first member 31) and the second member (second member 32) provided around the first member and having the refractive index different from the refractive index of the first member. The filling material is provided around the first structure and has the refractive index different from the refractive index of the second member.

The photodetector (imaging device 1) according to the present embodiment is provided with the light-guiding section 40 that includes the filling material 35 and the columnar structure 30 including the first member 31 and the second member 32. This makes it possible to efficiently condense incoming light on the photoelectric conversion section 12. It is possible to implement a photodetector that is able to efficiently condense light.

Next, descriptions are given of modification examples of the present disclosure. Hereinafter, components similar to those of the foregoing embodiment are denoted by the same reference numerals, and descriptions thereof are omitted as appropriate.

### 2. Modification Examples

### (2-1. Modification Example 1)

The description has been given, in the foregoing embodiment, of the example in which the structure 30 of each of the pixel Pr, the pixel Pg, and the pixel Pb is configured using a plurality of materials. However, the structure 30 configured by the plurality of materials may be provided only in one or two types of the pixels P of the pixel Pr, the pixel Pg, or the pixel Pb.

For example, the light of the blue wavelength region and the light of the green wavelength region tend to have a larger phase change with respect to a change in a width (diameter) of the structure 30 width (diameter), as compared with the light of the red wavelength region. Therefore, the pixel Pg and the pixel Pb may be provided with the light-guiding section 40 that includes the structure 30 including a plurality of members (e.g., first member 31 and second member 32).

As described above, by arranging the structure 30 including the plurality of members at positions corresponding to the pixel Pg and the pixel Pb (e.g., above the photoelectric conversion sections of the pixel Pg and the pixel Pb), it is possible to design a more accurate phase distribution. In other words, it is desirable to arrange the structure 30 including the plurality of members on a pixel that photoelectrically converts light of a wavelength range having a shorter wavelength than the light of the red wavelength range.

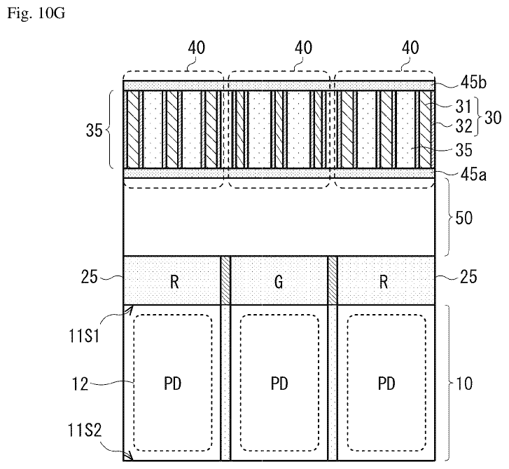

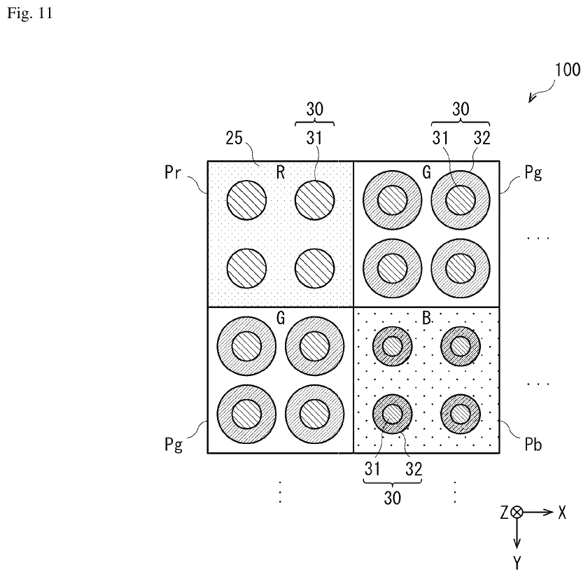

FIG. 11 is a diagram illustrating an example of a planar configuration of an imaging device according to Modification Example 1 of the present disclosure. FIGS. 12A and 12B are each a diagram illustrating an example of a cross-sectional configuration of the imaging device according to Modification Example 1. As in the examples illustrated FIGS. 11 and 12A, the pixel Pg and the pixel Pb may each include the structure 30 configured by the first member 31 and the second member 32. In addition, as in the examples illustrated in FIGS. 11 and 12B, the pixel Pr may include the structure 30 configured by the first member 31. It is possible to increase the number of possible combinations of phase values which can be adopted by light beams of respective wavelength bands, thus making it possible to perform high-precision phase design.

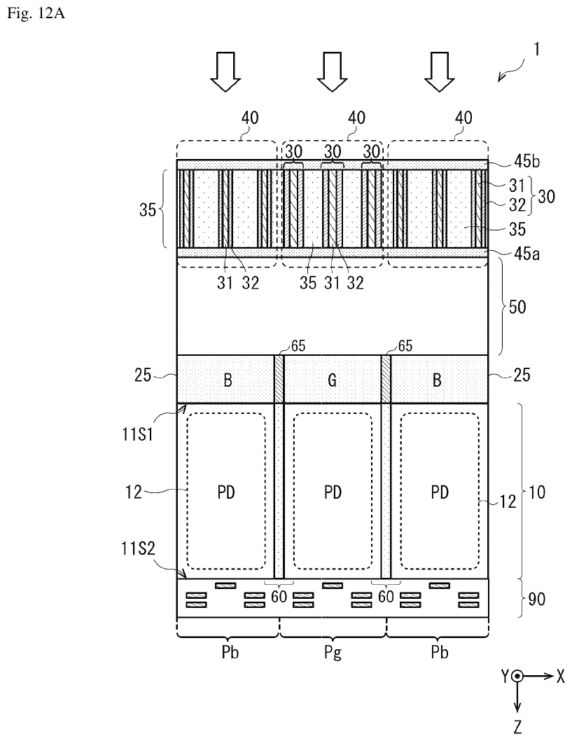

FIG. 13 is a diagram illustrating another example of the planar configuration of the imaging device according to Modification Example 1 of the present disclosure. As in the example illustrated in FIG. 13, the pixel Pb may include the structure 30 configured by the first member 31 and the second member 32. In addition, the pixel Pg and the pixel Pr may each include the structure 30 configured by the first member 31. It is to be noted that, as in the examples illustrated in FIGS. 11 to 13, the widths (diameters) of the first member 31 and the second member 32 of each of the structures 30 of the pixel Pb, the pixel Pg, and the pixel Pr may be formed to allow the respective sizes (widths) to differ.

In a case where a pixel Pc including the filter 25 of Cy, a pixel Pm including the filter 25 of Mg, and a pixel Py including the filter 25 of Ye are arranged, only one or two types of the pixels P may be provided with the structure 30 configured by the plurality of materials.

### (2-2. Modification Example 2)

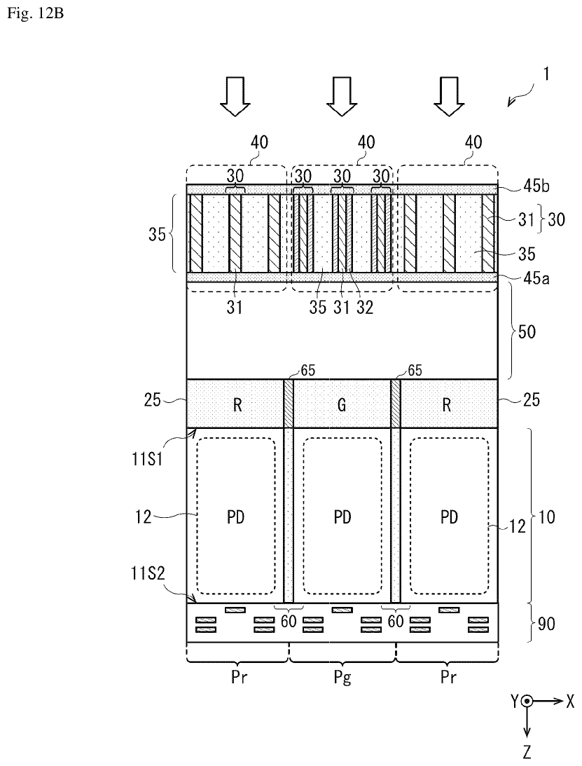

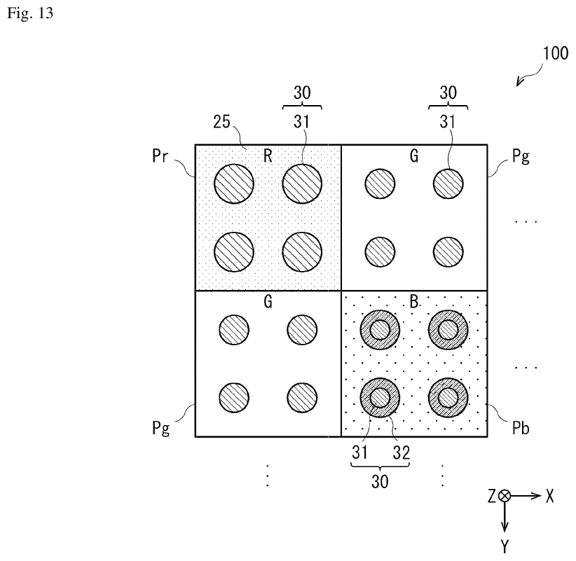

FIGS. 14 and 15 are each an explanatory diagram of a configuration example of a light-guiding section of an imaging device according to Modification Example 2. The description has been given, in the foregoing embodiment and modification example, of the configuration example of the light-guiding section 40 including the structure 30. The shape of the structure 30 of the light-guiding section 40 is not limited to the example described above. The shape of the structure 30 is appropriately modifiable, and may be, for example, a quadrangular shape in a plan view, as in the example illustrated in FIG. 14.

In addition, for example, the shape of the structure 30 may be a cross shape in a plan view, as in the example illustrated in FIG. 15. It is to be noted that the shape of the structure 30 may be a polygon, an ellipse, or another shape.

### (2-3. Modification Example 3)

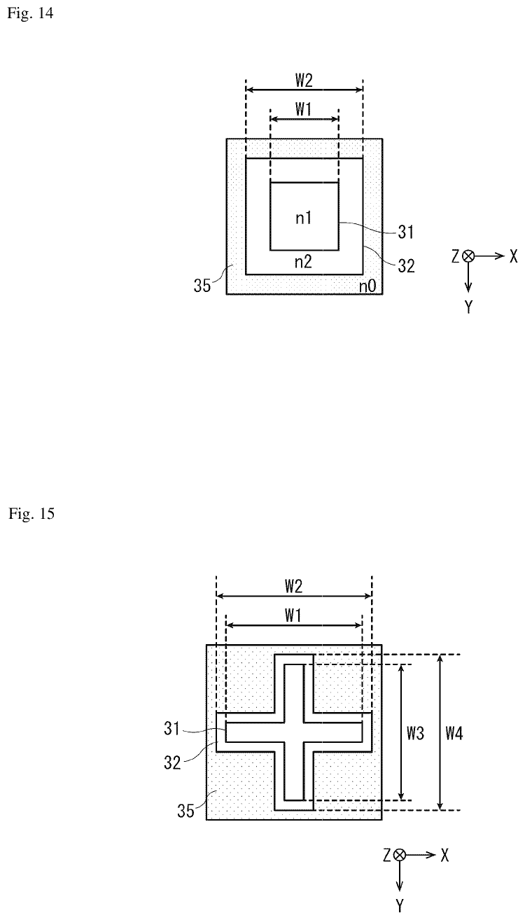

FIG. 16 is an explanatory diagram of a configuration example of a light-guiding section of an imaging device according to Modification Example 3. The structure 30 of the light-guiding section 40 may have a configuration in which three or more materials are combined. For example, as in the example illustrated in FIG. 16, the structure 30 may include a third member 33 provided around the second member 32.

The third member 33 of the structure 30 has a refractive index different from a refractive index of a surrounding medium. The third member 33 has a refractive index different from, for example, the refractive index of the second member 32 and the refractive index of the filling material 35 arranged around the third member 33. For example, the third member 33 may have a refractive index higher than the refractive index of the second member 32. In addition, the third member 33 may have a refractive index higher than the refractive index of the filling material 35.

In addition, for example, the third member 33 may have a refractive index lower than the refractive index of the second member 32. In addition, the third member 33 may have a refractive index lower than the refractive index of the filling material 35. It is to be noted that the first member 31 may have a refractive index higher than the refractive index of the third member 33, for example. Also in the case of the present modification example, it is possible to obtain effects similar to those of the foregoing embodiment.

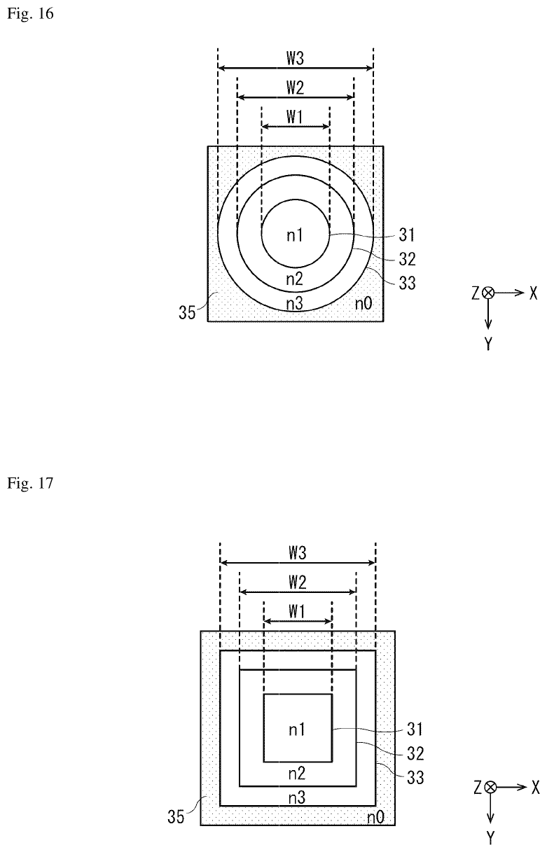

It is to be noted that the shape of the structure 30 is appropriately modifiable. As in the example illustrated in FIG. 16, the structure 30 may have a circular shape in a plan view. As in the example illustrated in FIG. 17, the structure 30 may have a quadrangular shape in a plan view.

### (2-4. Modification Example 4)

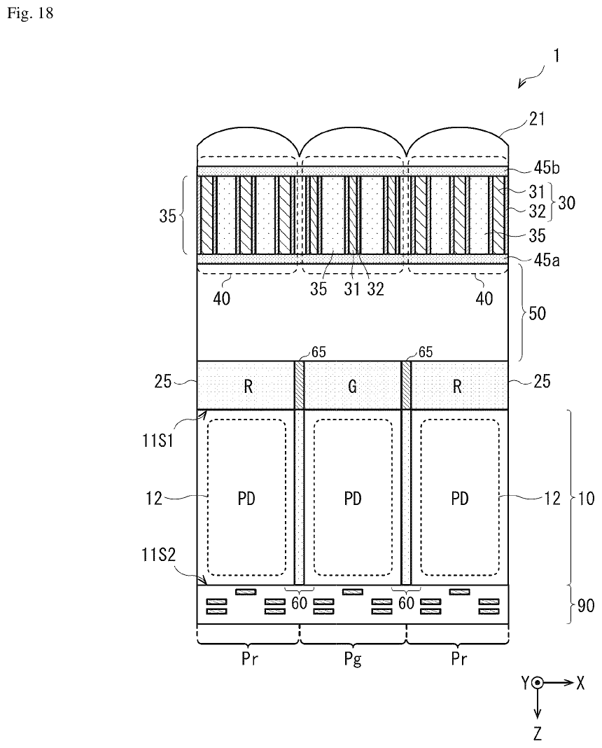

FIG. 18 is a diagram illustrating an example of a cross-sectional configuration of an imaging device according to Modification Example 4. As illustrated in FIG. 18, the imaging device 1 may include a lens section 21. The lens section 21 guides light incident from above to a side of the filter 25 and the photoelectric conversion section 12. The lens section 21 is an optical member also called an on-chip lens. The lens section 21 is provided above the light-guiding section 40, for example, for each pixel P or for each plurality of pixels P.

Light from a subject is incident on the lens section 21 via an optical system such as an imaging lens. The photoelectric conversion section 12 can photoelectrically convert light incident via the lens section 21, the light-guiding section 40, and the filter 25. It is to be noted that the lens section 21 may be provided between the light-guiding section 40 and the filter 25. The lens section 21 can also be referred to as an inner lens.

### (2-5. Modification Example 5)

The light-guiding section 40, which is an optical element, may be configured as a lens that condense light, depending on design of the structure 30. In addition, the light-guiding section 40 may be configured as an optical element that controls a polarization state of light. In these cases, the light-guiding section 40 is referred to as a metalens, a polarizing metalens, or the like.

In addition, for example, the light-guiding section 40 may be configured as a filter that selectively transmits light of a particular wavelength region, of incoming light.

The light-guiding section 40 may be configured as an optical element (referred to as a deflector) that changes a traveling direction of light of a particular wavelength region. The optical element (light-guiding section 40) and the photodetector according to the present disclosure are applicable to various apparatuses.

### 3. Application Example

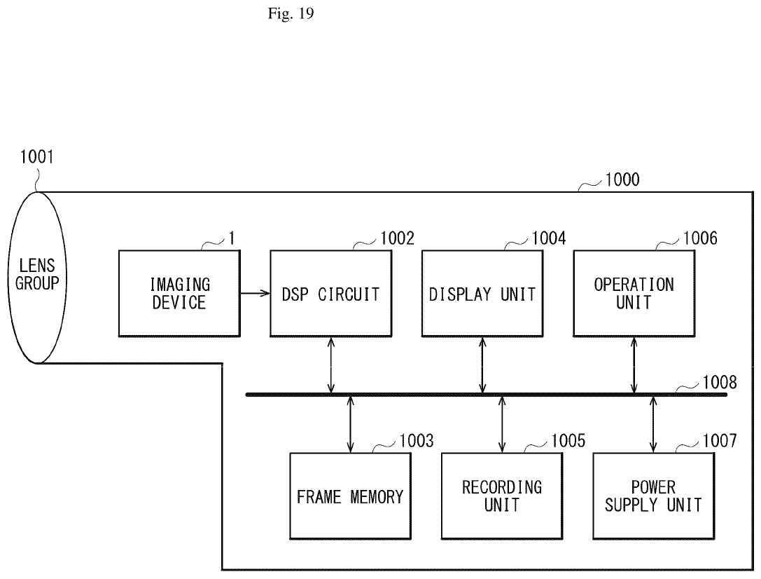

The above-described imaging device 1 or the like is applicable, for example, to any type of electronic apparatus with an imaging function including a camera system such as a digital still camera or a video camera, a mobile phone having an imaging function, and the like. FIG. 19 illustrates a schematic configuration of an electronic apparatus 1000.

The electronic apparatus 1000 includes, for example, a lens group 1001, the imaging device 1, a DSP (Digital Signal Processor) circuit 1002, a frame memory 1003, a display unit 1004, a recording unit 1005, an operation unit 1006, and a power supply unit 1007. They are coupled to each other via a bus line 1008.

The lens group 1001 takes in incident light (image light) from a subject, and forms an image on an imaging surface of the imaging device 1. The imaging device 1 converts the amount of incident light formed as an image on the imaging surface by the lens group 1001 into electric signals on a pixel-by-pixel basis, and supplies the DSP circuit 1002 with the electric signals as pixel signals.

The DSP circuit 1002 is a signal processing circuit that processes signals supplied from the imaging device 1. The DSP circuit 1002 outputs image data obtained by processing the signals from the imaging device 1. The frame memory 1003 temporarily holds the image data processed by the DSP circuit 1002 on a frame-by-frame basis.

The display unit 1004 includes, for example, a panel-type display device such as a liquid crystal panel or an organic EL (Electro Luminescence) panel, and records image data of a moving image or a still image captured by the imaging device 1 in a recording medium such as a semiconductor memory or a hard disk.

The operation unit 1006 outputs an operation signal for a variety of functions of the electronic apparatus 1000 in accordance with an operation by a user. The power supply unit 1007 appropriately supplies the DSP circuit 1002, the frame memory 1003, the display unit 1004, the recording unit 1005, and the operation unit 1006 with various kinds of power for operations of these supply targets.

### 4. Practical Application Examples

### (Example of Practical Application to Mobile Body)

The technology (the present technology) according to the present disclosure is applicable to a variety of products. For example, the technology according to the present disclosure may be achieved as a device mounted on any type of mobile body such as an automobile, an electric vehicle, a hybrid electric vehicle, a motorcycle, a bicycle, a personal mobility, an aircraft, a drone, a vessel, or a robot.

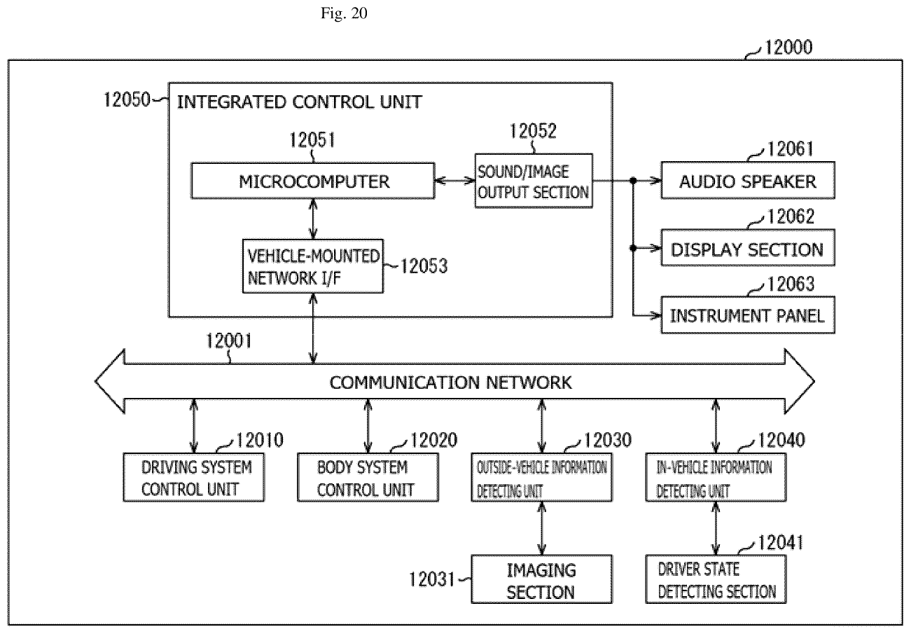

FIG. 20 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 20, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 20, an audio speaker 12061, a display section 12062, and an instrument panel 12063 are illustrated as the output device. The display section 12062 may, for example, include at least one of an on-board display and a head-up display.

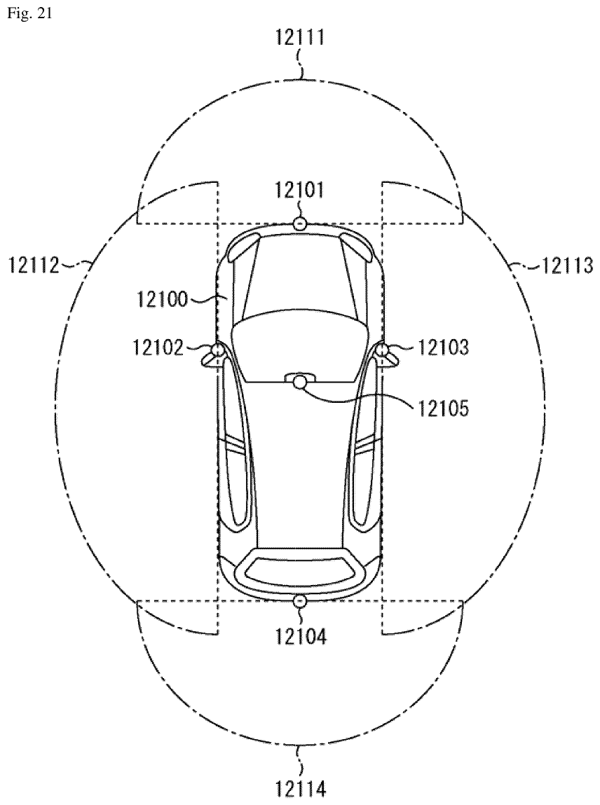

FIG. 21 is a diagram depicting an example of the installation position of the imaging section 12031.

In FIG. 21, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 21 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or maybe an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object.

When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of the mobile body control system to which the technology according to an embodiment of the present disclosure is applicable. The technology according to an embodiment of the present disclosure is applicable to the imaging section 12031, for example, of the configurations described above. Specifically, for example, the imaging device 1 or the like can be applied to the imaging section 12031. Applying the technology according to an embodiment of the present disclosure to the imaging section 12031 enables obtainment of a photographed image having high definition, thus making it possible to perform highly accurate control utilizing the photographed image in the mobile body control system.

### (Example of Practical Application to Endoscopic Surgery System)

The technology according to an embodiment of the present disclosure (present technology) is applicable to various products. For example, the technology according to an embodiment of the present disclosure may be applied to an endoscopic surgery system.

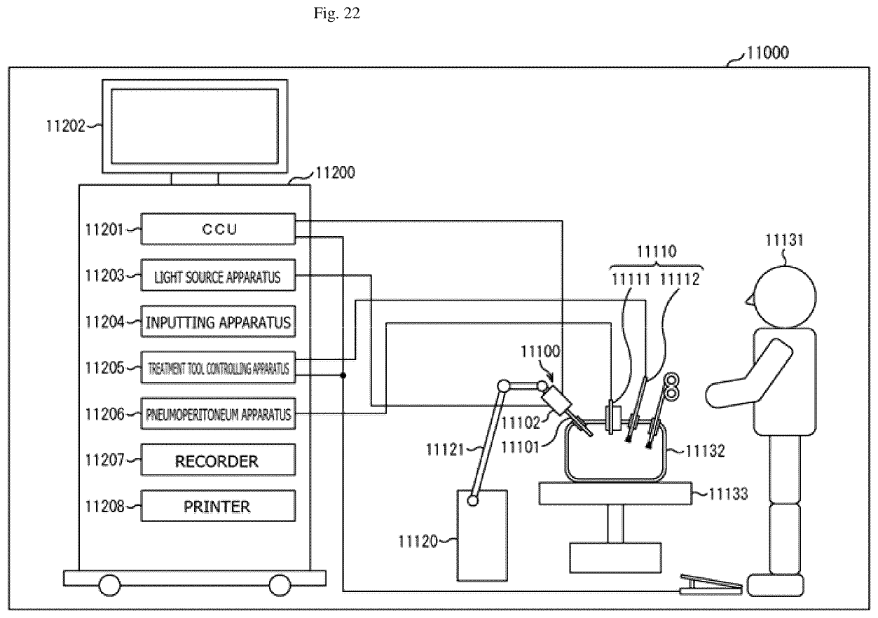

FIG. 22 is a view depicting an example of a schematic configuration of an endoscopic surgery system to which the technology according to an embodiment of the present disclosure (present technology) can be applied.

In FIG. 22, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted as a rigid endoscope having the lens barrel 11101 of the hard type. However, the endoscope 11100 may otherwise be included as a flexible endoscope having the lens barrel 11101 of the flexible type.

The lens barrel 11101 has at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be output is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

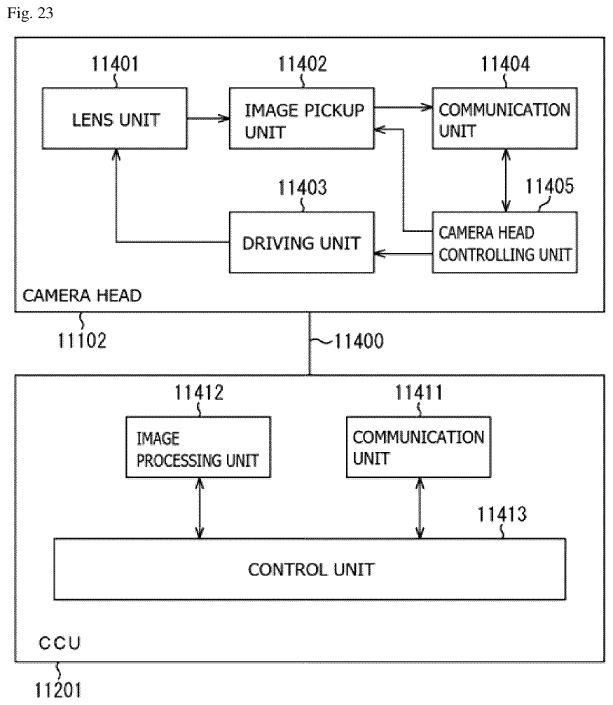

FIG. 23 is a block diagram depicting an example of a functional configuration of the camera head 11102 and the CCU 11201 depicted in FIG. 22.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three-dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given hereinabove of one example of the endoscopic surgery system, to which the technology according to an embodiment of the present disclosure is applicable. The technology according to an embodiment of the present disclosure is suitably applicable to, for example, the image pickup unit 11402 provided in the camera head 11102 of the endoscope 11100 of the configurations described above. Applying the technology according to an embodiment of the present disclosure to the image pickup unit 11402 enables the image pickup unit 11402 to have high sensitivity, thus making it possible to provide the endoscope 11100 having high definition.

Although the description has been given hereinabove of the present disclosure with reference to the embodiment, the modification examples, the application example, and the practical application examples, the present technology is not limited to the foregoing embodiment and the like, and may be modified in a wide variety of ways. For example, although the foregoing modification examples have been described as modification examples of the foregoing embodiment, the configurations of the respective modification examples may be combined as appropriate. For example, the present disclosure is not limited to a back-illuminated image sensor, and is also applicable to a front-illuminated image sensor.

An optical element according to an embodiment of the present disclosure includes a structure having a columnar shape and including a first member and a second member provided around the first member and having a refractive index different from a refractive index of the first member, and a filling material provided around the structure and having a refractive index different from the refractive index of the second member. Therefore, it is possible to increase the number of possible combinations of phase values which can be adopted by light beams of respective wavelength regions, thus making it possible to appropriately guide incoming light. It is possible to implement an optical element that is able to efficiently condense light.

A photodetector according to an embodiment of the present disclosure includes a first light-guiding member including a first structure having a columnar shape and the filling material provided around the first structure, and a first photoelectric conversion element that photoelectrically converts light incident via the first light-guiding member. The first structure includes the first member and the second member provided around the first member and having the refractive index different from the refractive index of the first member. The filling material is provided around the first structure and has the refractive index different from the refractive index of the second member.

Therefore, it is possible to increase the number of possible combinations of phase values which can be adopted by light beams of respective wavelength regions, thus making it possible to appropriately guide incoming light. It is possible to implement a photodetector that is able to efficiently condense light.

It is to be noted that the effects described herein are merely exemplary and are not limited to the description, and may further include other effects. In addition, the present disclosure may also have the following configurations.

(1)

An optical element including:
a structure having a columnar shape and including a first member and a second member provided around the first member, the second member having a refractive index different from a refractive index of the first member; and
a filling material provided around the structure and having a refractive index different from the refractive index of the second member.
   (2)

The optical element according to (1), in which
the refractive index of the first member is higher than the refractive index of the second member, and
the refractive index of the second member is higher than the refractive index of the filling material.
   (3)

The optical element according to (1) or (2), in which
the refractive index of the first member is higher than the refractive index of the filling material, and
the refractive index of the filling material is higher than the refractive index of the second member.
   (4)

The optical element according to any one of (1) to (3), in which the structure has a width equal to or less than a wavelength of visible light or a width equal to or less than a wavelength of infrared light.

(5)

The optical element according to any one of (1) to (4), further including a plurality of the structures, in which
the filling material is provided to fill between the plurality of the structures adjacent to each other.
   (6)

The optical element according to any one of (1) to (5), in which the structure includes a first structure and a second structure which have widths different from each other.

(7)

The optical element according to any one of (1) to (6), in which the structure includes a third member provided around the second member and having a refractive index different from the refractive index of the second member.

(8)

The optical element according to any one of (1) to (7), in which the structure has a columnar shape.

(9)

The optical element according to any one of (1) to (7), in which the structure has a rectangular shape.

(10)

The optical element according to any one of (1) to (7), in which the structure has a cross shape.

(11)

A photodetector including:
a first light-guiding member including a first structure and a filling material provided around the first structure; and
a first photoelectric conversion element that photoelectrically converts light incident via the first light-guiding member, in which
the first structure includes a first member and a second member provided around the first member, the second member having a refractive index different from a refractive index of the first member, and
the filling material is provided around the first structure and has a refractive index different from the refractive index of the second member.
   (12)

The photodetector according to (11), in which
the refractive index of the first member is higher than the refractive index of the second member, and
the refractive index of the second member is higher than the refractive index of the filling material.
   (13)

The photodetector according to (11) or (12), in which
the refractive index of the first member is higher than the refractive index of the filling material, and
the refractive index of the filling material is higher than the refractive index of the second member.
   (14)

The photodetector according to any one of (11) to (13), in which the first structure has a width equal to or less than a wavelength of visible light or a width equal to or less than a wavelength of infrared light.

(15)

The photodetector according to any one of (11) to (14), in which the first structure is provided above the first photoelectric conversion element and disperses incident light.

(16)

The photodetector according to any one of (11) to (15), further including:
a second light-guiding member including a second structure and the filling material provided around the second structure;
a second photoelectric conversion element that photoelectrically converts light incident via the second light-guiding member;
a third light-guiding member including a third structure and the filling material provided around the third structure; and
a third photoelectric conversion element that photoelectrically converts light incident via the third light-guiding member.
   (17)

The photodetector according to any one of (11) to (16), further including a first filter provided between the first light-guiding member and the first photoelectric conversion element, the first filter transmitting blue light.

(18)

The photodetector according to (17), further including a second filter provided between the second light-guiding member and the second photoelectric conversion element, the second filter transmitting green light, in which
the second structure includes the first member and the second member provided around the first member.
   (19)

The photodetector according to (18), further including a third filter provided between the third light-guiding member and the third photoelectric conversion element, the third filter transmitting red light, in which
the third structure includes the first member and the second member provided around the first member.
   (20)

The photodetector according to any one of (11) to (19), in which the first structure includes a third member provided around the second member, and in which the third member has a refractive index different from the refractive index of the second member.

(21)

An electronic apparatus including:
an optical system; and
a photodetector that receives light transmitted through the optical system,
the photodetector including
a first light-guiding member including a first structure and a filling material provided around the first structure, and
a first photoelectric conversion element that photoelectrically converts light incident via the first light-guiding member, in which
the first structure includes a first member and a second member provided around the first member, the second member having a refractive index different from a refractive index of the first member, and
the filling material is provided around the first structure and has a refractive index different from the refractive index of the second member.

It should be understood by those skilled in the art that various modifications, combinations, sub-combinations and alterations may occur depending on design re-quirements and other factors insofar as they are within the scope of the appended claims or the equivalents thereof.

### REFERENCE NUMERALS LIST

1 imaging device
10 semiconductor layer
12 photoelectric conversion section
25 filter
30 structure
31 first member
32 second member
33 third member
35 filling material or filling member
40 light-guiding section
50 insulating layer

What is claimed is:

1. An optical element, comprising:
a structure including a first member and a second member provided around the first member, wherein the second member has a refractive index different from a refractive index of the first member; and
a filling material provided around the structure and having a refractive index different from the refractive index of the second member.

2. The optical element according to claim 1,
wherein the refractive index of the first member is higher than the refractive index of the second member, and
wherein the refractive index of the second member is higher than the refractive index of the filling material.

3. The optical element according to claim 1,
wherein the refractive index of the first member is higher than the refractive index of the filling material, and
wherein the refractive index of the filling material is higher than the refractive index of the second member.

4. The optical element according to claim 1, wherein the structure has a width equal to or less than a wavelength of visible light or a width equal to or less than a wavelength of infrared light.

5. The optical element according to claim 1, further comprising:
a plurality of the structures, wherein the filling material is provided to fill between the plurality of the structures adjacent to each other.

6. The optical element according to claim 1, wherein the structure includes a first structure and a second structure which have widths different from each other.

7. The optical element according to claim 1, wherein the structure includes a third member provided around the second member, wherein the third member has a refractive index different from the refractive index of the second member.

8. The optical element according to claim 1, wherein the structure has a columnar shape.

9. The optical element according to claim 1, wherein the structure has a rectangular shape.

10. The optical element according to claim 1, wherein the structure has a cross shape.

11. A photodetector, comprising:
a first light-guiding member including a first structure and a filling material provided around the first structure; and
a first photoelectric conversion element that photoelectrically converts light incident via the first light-guiding member,
wherein the first structure includes a first member and a second member provided around the first member, the second member having a refractive index different from a refractive index of the first member, and
wherein the filling material is provided around the first structure and has a refractive index different from the refractive index of the second member.

12. The photodetector according to claim 11,
wherein the refractive index of the first member is higher than the refractive index of the second member, and
wherein the refractive index of the second member is higher than the refractive index of the filling material.

13. The photodetector according to claim 11,
wherein the refractive index of the first member is higher than the refractive index of the filling material, and
wherein the refractive index of the filling material is higher than the refractive index of the second member.

14. The photodetector according to claim 11, wherein the first structure has a width equal to or less than a wavelength of visible light or a width equal to or less than a wavelength of infrared light.

15. The photodetector according to claim 11, wherein the first structure is provided above the first photoelectric conversion element and disperses incident light.

16. The photodetector according to claim 11, further comprising:
a second light-guiding member including a second structure and the filling material provided around the second structure;
a second photoelectric conversion element that photoelectrically converts light incident via the second light-guiding member;
a third light-guiding member including a third structure and the filling material provided around the third structure; and
a third photoelectric conversion element that photoelectrically converts light incident via the third light-guiding member.

17. The photodetector according to claim 16, further comprising:
a first filter provided between the first light-guiding member and the first photoelectric conversion element, wherein the first filter transmits blue light.

18. The photodetector according to claim 17, further comprising:
a second filter provided between the second light-guiding member and the second photoelectric conversion element,
wherein the second filter transmits green light, and
wherein the second structure includes the first member and the second member provided around the first member.

19. The photodetector according to claim 18, further comprising:
a third filter provided between the third light-guiding member and the third photoelectric conversion element,
wherein the third filter transmits red light, and
wherein the third structure includes the first member and the second member provided around the first member.

20. The photodetector according to claim 11, wherein the first structure includes a third member provided around the second member, and wherein the third member has a refractive index different from the refractive index of the second member.

21. An electronic apparatus, comprising:
an optical system; and
a photodetector that receives light transmitted through the optical system,
the photodetector including:
a first light-guiding member including a first structure and a filling material provided around the first structure; and
a first photoelectric conversion element that photoelectrically converts light incident via the first light-guiding member,
wherein the first structure includes a first member and a second member provided around the first member, the second member having a refractive index different from a refractive index of the first member, and
wherein the filling material is provided around the first structure and has a refractive index different from the refractive index of the second member.
